(19) United States
(12) Patent Application Publication
(10) Pub. No.: US 2026/0315136 A1
(43) Pub. Date: Oct. 15, 2026

(54) TREATMENT TOOL FOR ENDOSCOPE

(71) Applicant: OLYMPUS MEDICAL SYSTEMS CORP., Tokyo (JP)

(72) Inventors: Mikiya KUROSAKA, Kodaira-shi (JP); Kikuo TAKI, Higashiyamato-shi (JP); Yoichi SAKURADA, Higashimurayama-shi (JP); Daiki HAGIWARA, Hachioji-shi (JP)

(21) Appl. No.: 19/562,489

(22) Filed: Mar. 10, 2026

Related U.S. Application Data
(60) Provisional application No. 63/788,486, filed on Apr. 14, 2025.

(51) Int. Cl. A61B 18/14; A61B 90/00; A61B 18/00

(52) U.S. Cl. CPC A61B 18/1445; A61B 90/03; A61B 2018/00172; A61B 2018/00184; A61B 2018/0091; A61B 2018/00982; A61B 2090/034

(57) ABSTRACT

The treatment tool for an endoscope includes a coil sheath, a resin tube configured to cover an outer periphery of the coil sheath, a sheath connector connected to a distal end of the coil sheath, a distal member located distally relative to a distal end of the sheath connector, and a housing configured to support the distal member and cover a part of the distal member, a proximal portion of the housing covering a distal portion of the sheath connector from outside and being supported pivotably around a longitudinal axis of the coil sheath relative to the sheath connector, a distal end surface of the coil sheath being joined to a proximal end surface of the sheath connector, and an outer diameter of at least a part of the resin tube being smaller than a maximum width of an outer surface of the housing in a radial direction.

### BACKGROUND OF THE INVENTION

### Field of the Invention

The present disclosure relates to a treatment tool for an endoscope.

Priority is claimed on US Provisional Patent Application No. 63/788,486, filed Apr. 14, 2025, the entire content of which is incorporated herein by reference.

### DESCRIPTION OF RELATED ART

In the related art, in endoscopic therapy, a treatment tool for an endoscope is used, in which a treatment part, such as a forceps, attached to a distal end pivots (for example, US Patent No. 7534253 or US Patent Application Publication No. 2022/0395287). The treatment part such as a forceps is pivotally supported in the housing or the like.

### SUMMARY OF THE INVENTION

In order to solve the above-mentioned problems, the present invention proposes the following means.

A treatment tool for an endoscope according to a first aspect of the present disclosure includes a coil sheath; a resin tube configured to cover an outer periphery of the coil sheath; a sheath connector connected to a distal end of the coil sheath; a distal member located distally relative to a distal end of the sheath connector; and a housing configured to support the distal member and cover a part of the distal member, a proximal portion of the housing covering a distal portion of the sheath connector from outside and being supported pivotably around a longitudinal axis of the coil sheath relative to the sheath connector, a distal end end surface of the coil sheath being joined to a proximal end surface of the sheath connector, and an outer diameter of at least a part of the resin tube being smaller than a maximum width of an outer surface of the housing in a radial direction of the coil sheath.

A treatment tool for an endoscope according to a second aspect of the present disclosure includes a coil sheath; a resin tube configured to cover an outer surface of at least a proximal portion of the coil sheath; and a handle main body disposed on the proximal portion of the coil sheath, the proximal portion of the coil sheath being inserted into the handle main body, and the resin tube being pressed between the proximal portion of the coil sheath and the handle main body to fix the coil sheath to the handle main body.

A treatment tool for an endoscope according to a third aspect of the present disclosure includes a coil sheath; a handle main body connected to a proximal portion of the coil sheath; a cover attached to the handle main body; a resin tube configured to cover an outer surface of at least the proximal portion of the coil sheath; a sheath connector connected to a distal end of the coil sheath; a distal member located distally relative to a distal end of the sheath connector; and a housing configured to support the distal member and cover a part of the distal member, the handle main body having a plurality of partition walls extending in a direction intersecting an attachment direction of the cover and arranged side by side with a gap therebetween, the proximal portion of the coil sheath being inserted and fixed into the gap, and an outer diameter of a distal portion of the resin tube being greater than a width of the gap and smaller than a maximum width of the housing.

### BRIEF DESCRIPTION OF THE DRAWINGS

FIG. 1 is an overall view of an endoscopic treatment system including a treatment tool according to a first embodiment.

FIG. 2 is an overall view showing the treatment tool.

FIG. 3 is a perspective view of a distal end portion of the treatment tool.

FIG. 4 is a side view of the distal end portion of the treatment tool.

FIG. 5 is a cross-sectional view of the distal end portion of the treatment tool.

FIG. 6 is a cross-sectional view of a sheath and a wire.

FIG. 7 is a view showing the wire.

FIG. 8 is a plan view of the distal end portion of the treatment tool.

FIG. 9 is a cross-sectional view of the distal end portion of the treatment tool.

FIG. 10 is a view showing an operation of the link mechanism.

FIG. 11 is a view showing an operation of the link mechanism.

FIG. 12 is a view showing an operation of the link mechanism.

FIG. 13 is a view showing an operation of the link mechanism.

FIG. 14 is a cross-sectional view of the distal end portion of the treatment tool with a forceps open.

FIG. 15 is a perspective view of a manipulation part.

FIG. 16 is a cross-sectional view of the manipulation part.

FIG. 17 is a view showing a cover.

FIG. 18 is a cross-sectional view along line X-X shown in FIG. 16.

FIG. 19 is a view showing a handle main body.

FIG. 20 is a view showing the handle main body.

FIG. 21 is a view showing the handle main body.

FIG. 22 is a cross-sectional view of a second handle main body and a slider.

FIG. 23 is a cross-sectional view of the second handle main body and the slider.

FIG. 24 is a view showing a variant of the treatment tool.

FIG. 25 is a cross-sectional view of a manipulation part of the variant.

### DETAILED DESCRIPTION OF THE INVENTION

### First embodiment

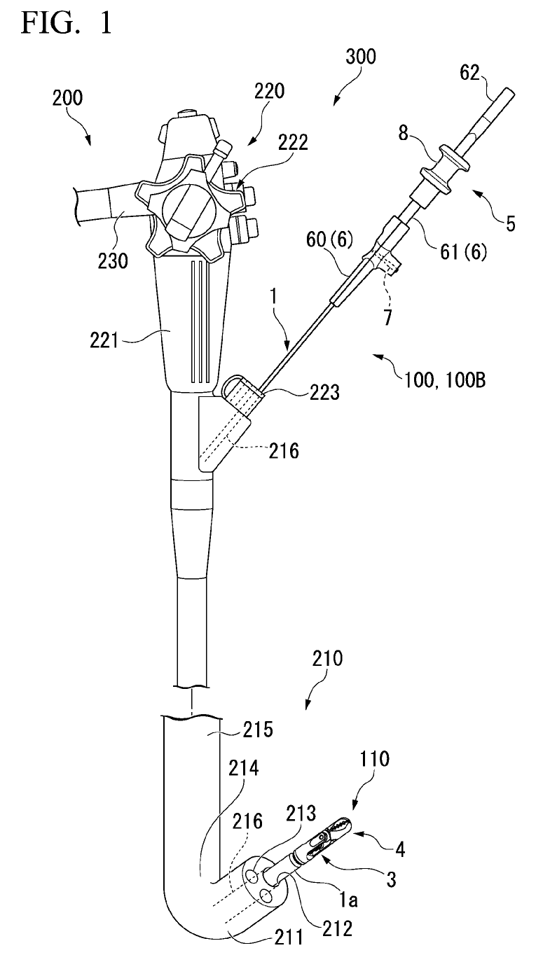

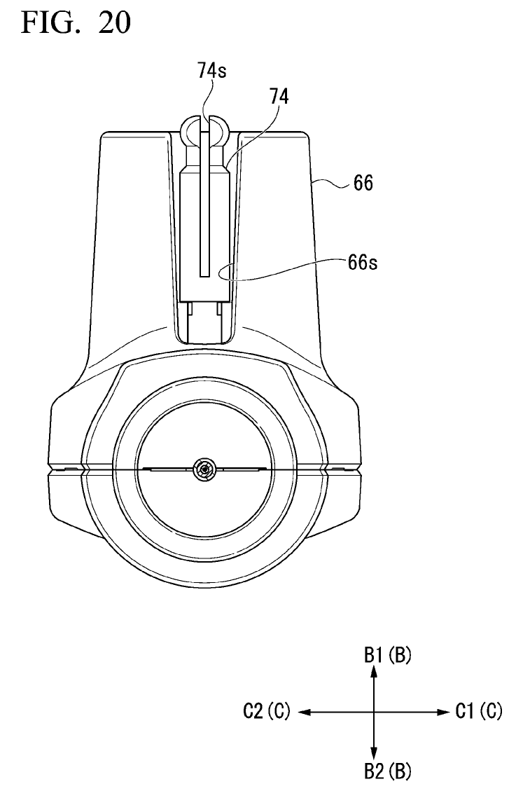

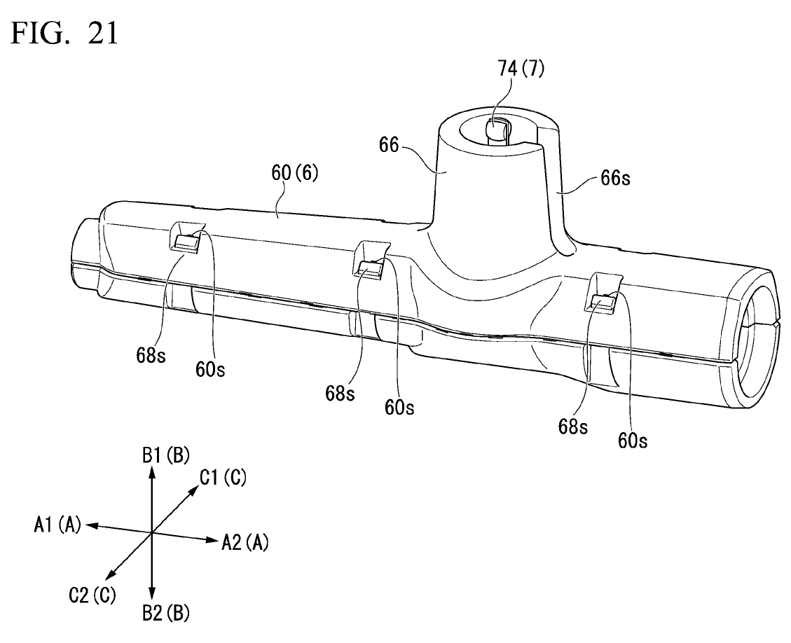

An endoscopic treatment system 300 including a treatment tool for an endoscope 100 according to a first embodiment of the present disclosure will be described with reference to FIGS. 1-23. FIG. 1 is an overall view of the endoscopic treatment system 300.

### Endoscopic treatment system 300

As shown in FIG. 1, the endoscopic treatment system 300 includes the treatment tool for an endoscope 100, and an endoscope 200. The treatment tool for an endoscope 100 is inserted into the endoscope 200 and used.

### Endoscope 200

The endoscope 200 is a known flexible endoscope, and includes an insertion part 210 inserted into the body from a distal end thereof, a manipulation part 220 attached to a proximal end of the insertion part 210, and a universal cord 230 attached to the manipulation part 220.

The insertion part 210 is a thin, elongated member that can be inserted into the lumen. The insertion part 210 has a distal end portion 211, a curved portion 214, and a flexible portion 215. The distal end portion 211, the curved portion 214, and the flexible portion 215 are connected from a distal end side in this order. A channel 216 into which the treatment tool for an endoscope 100 is inserted is provided in the insertion part 210. The distal end portion 211 is a provided with a distal end opening portion 212 of the channel 216 and an imaging unit 213.

The imaging unit 213 is equipped with an imaging element such as a CCD, a CMOS, or the like, and is capable of imaging an area that becomes a treatment target. The curved portion 214 curves according to the manipulation of the manipulation part 220 by a user. The flexible portion 215 is a tubular area with flexibility.

The manipulation part 220 is connected to the flexible portion 215. The manipulation part 220 has a grip 221, an input part 222, and a forceps port 223. The grip 221 is a member supported by the user. The input part 222 accepts manipulation input for curving the curved portion 214. The forceps port 223 is a proximal end opening portion of the channel 216.

The universal cord 230 connects the treatment tool for an endoscope 100 and external equipment. An imaging cable, an optical fiber cable, and the like, which output the imaging signal captured by the imaging unit 213 to the outside, are inserted into the universal cord 230.

### Treatment tool for endoscope 100

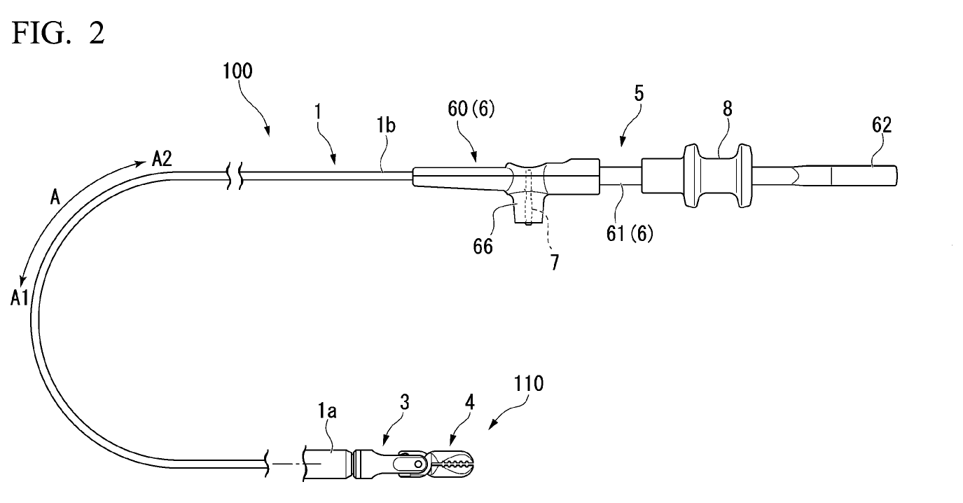

FIG. 2 is an overall view showing the treatment tool for an endoscope 100.

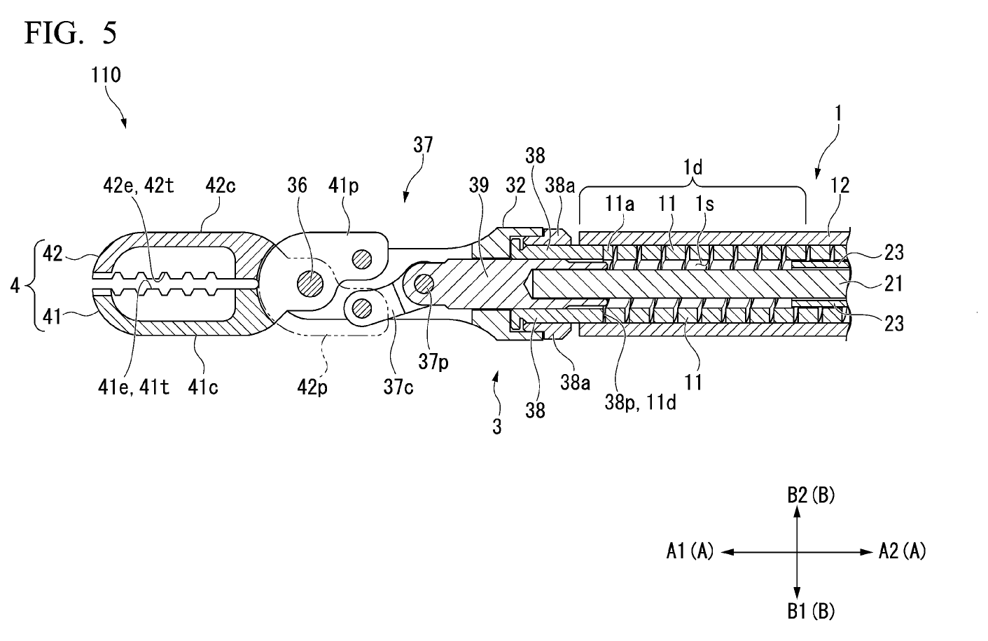

The treatment tool for an endoscope 100 (also referred to as a treatment tool 100) is a hemostasis forceps that cauterizes the affected area to stop bleeding. The treatment tool 100 includes a sheath 1, a wire 21 (see FIG. 5), a support member (holder) 3, a forceps (grasper, jaws) 4, and a manipulation part (handle, handle assembly) 5. In the following description, in a longitudinal axis direction (longitudinal direction, axial direction) A of the treatment tool 100, the side of the forceps 4 is referred to as “a distal end side (distal side) A1,” and the side of the manipulation part 5 is referred to as “a proximal end side (proximal side) A2.”

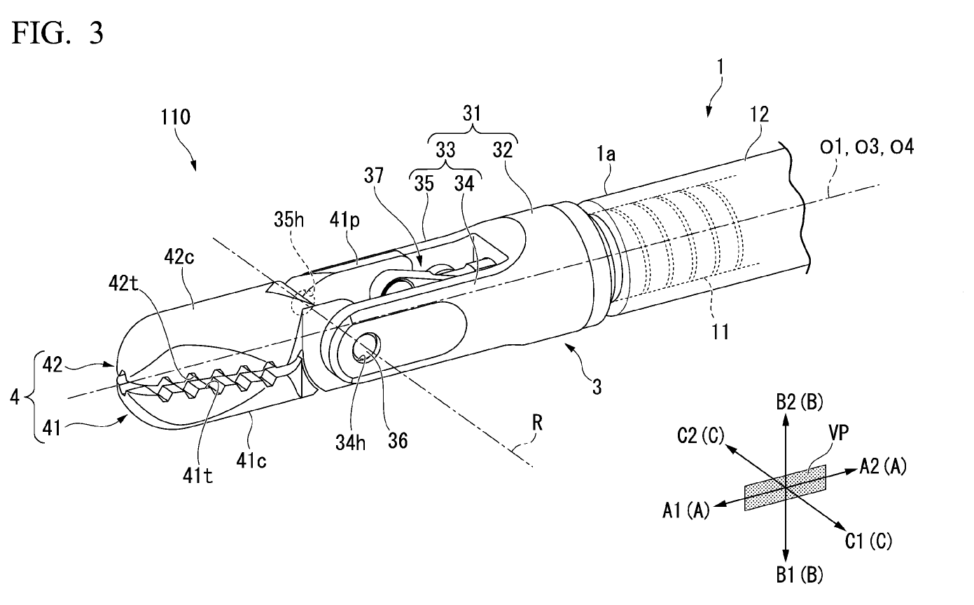

FIG. 3 is a perspective view of a distal end portion of the treatment tool 100.

The distal end portion of the treatment tool 100 is provided with the support member 3 and the forceps 4. The forceps 4 is pivotably supported by the support member 3. The support member 3 and the forceps 4 constitute “a treatment part (end effecter, distal member) 110” configured to treat an affected area. In the embodiment, while the treatment part 110 is the hemostasis forceps, the treatment part is not limited thereto. The treatment part may be a biopsy forceps, a high-frequency knife, a needle holder, or the like.

In the following description, a direction in which the forceps 4 is opened and closed is referred to as “an opening/closing direction B” or “an upward/downward direction B.” In addition, a direction perpendicular to the longitudinal direction A and the opening/closing direction B is referred to as “a widthwise direction C” or “a leftward/rightward direction C.” In addition, a surface parallel to the longitudinal direction A and the widthwise direction C is referred to as “a horizontal plane.” A surface parallel to the longitudinal direction A and the opening/closing direction B is referred to as “a vertical plane VP.”

The sheath 1 is an elongated member having flexibility and extending from a distal end 1a to a proximal end 1b. The sheath 1 can be inserted into the channel 216 of the endoscope 200. As shown in FIG. 1, when the sheath 1 is inserted into the channel 216, the distal end 1a of the sheath 1 can be protruded and retracted from the distal end opening portion 212 of the channel 216. The proximal end 1b of the sheath 1 is connected to the manipulation part 5. The sheath 1 may have insulation.

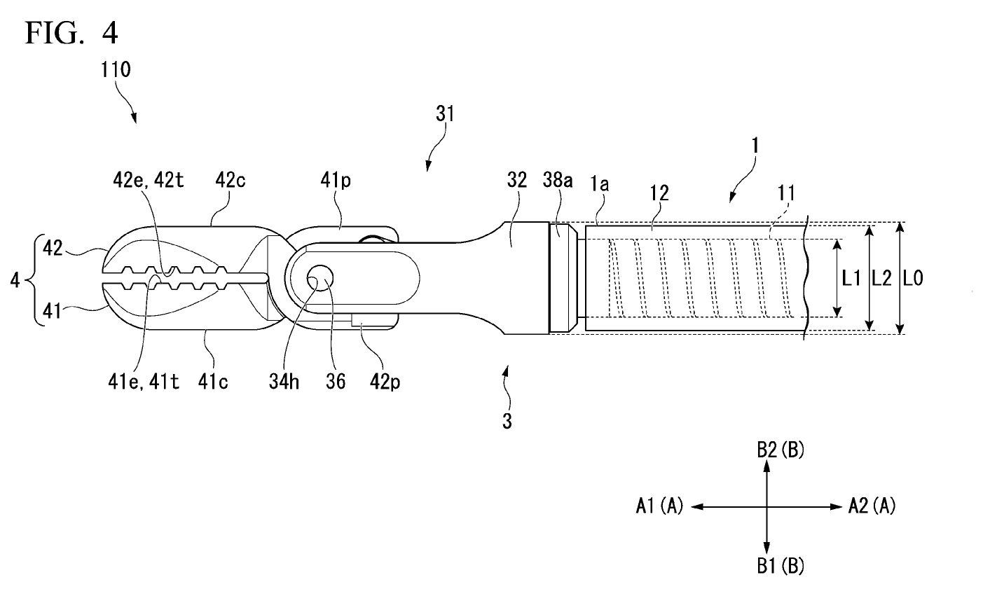

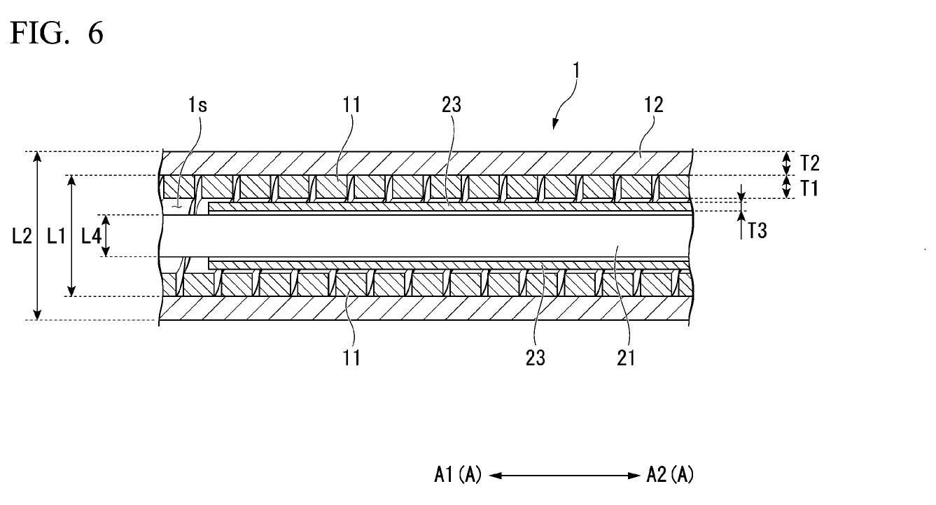

FIG. 4 is a side view of the distal end portion of the treatment tool 100. FIG. 5 is a cross-sectional view of the distal end portion of the treatment tool 100. The sheath 1 includes a coil sheath 11 formed by winding a metal solid wire in a spiral shape, and a resin tube 12 configured to cover an outer peripheral surface of the coil sheath 11. The coil sheath 11 is formed of a flat wire coil (see FIG. 6) made by winding a flat wire. The flat wire has a flat strip-like shape (with a cross section that is approximately rectangular or approximately oval, for example) made by crushing a round solid wire. The resin tube 12 is a heat-shrinkable tube made of a resin, for example, polyethylene or the like. The resin tube 12 is not limited to the heat-shrinkable tube, and may be, for example, a tube formed by extruding a resin directly onto the coil sheath 11.

FIG. 6 is a cross-sectional view of the sheath 1 and the wire 21.

An outer diameter L1 of the coil sheath 11 is 1.6 mm to 1.7 mm. A thickness T1 of the coil sheath 11 is about 0.3 mm. By using a flat wire coil for the coil sheath 11, the thickness T1 is reduced and a maximum outer diameter L2 of the sheath 1 is narrowed. Accordingly, a sufficient gap can be secured between the endoscope channel and the sheath 1, improving the suction effect using the channel. In addition, by using the flat wire coil for the coil sheath 11, the thickness T1 can be made thin while maintaining a moderate rigidity.

When the resin tube 12 is attached to the coil sheath 11 by heat-shrinking, the outer diameter L2 of the resin tube 12 is 2.0 mm to 2.5 mm, and more preferably, 2.1 mm to 2.3 mm. A thickness T2 of the resin tube 12 is 0.2 mm to 0.4 mm, and more preferably, about 0.3 mm. The thickness T2 of the resin tube 12 is increased to improve heat resistance, while the maximum outer diameter L2 of the sheath 1 is narrowed.

The wire 21 is inserted through an internal space 1s of the coil sheath 11. A distal end of the wire 21 is connected to the forceps 4 via a connector 39 or the like. A proximal end of the wire 21 is connected to the manipulation part 5.

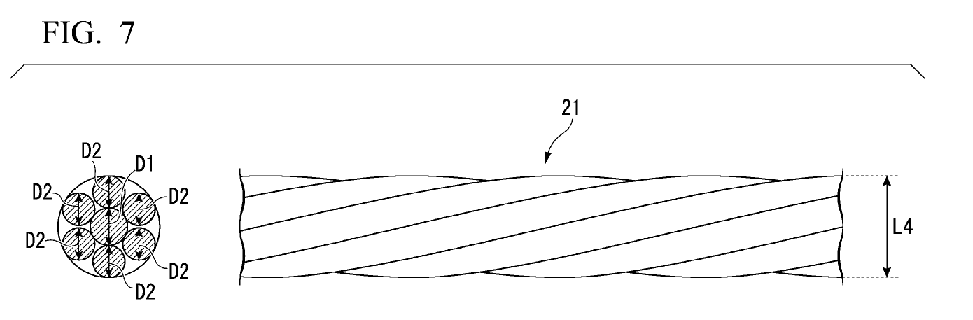

FIG. 7 is a view showing the wire 21.

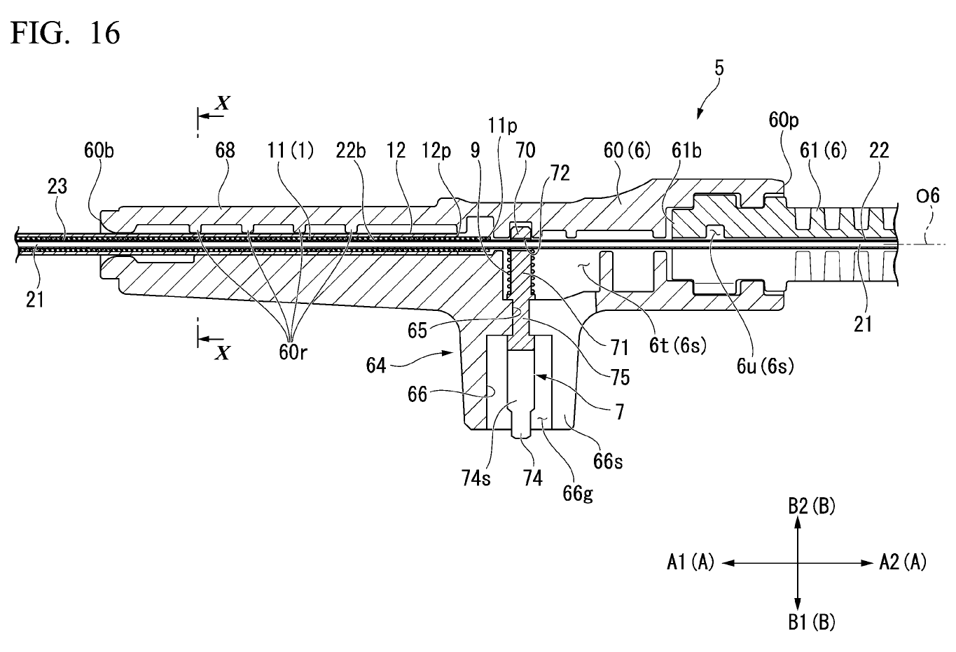

The wire 21 has conductivity and transmits high frequency current to the forceps 4. An outer diameter L4 of the wire 21 is 0.4 mm to 0.6 mm. The wire 21 is formed by twisting together multiple solid wires. An outer diameter D1 of the central stranded wire is larger than an outer diameter D2 of the surrounding stranded wires. The proximal end portion of the wire 21 is inserted into a pipe 22 (see FIG. 16) inside the manipulation part 5. Further, the wire 21 is not limited to the stranded wire, and may be any conductive member such as a metal single wire, a metal coil wire (coil tube), or the like.

As shown in FIG. 6, an inner sheath 23 is disposed on an outer periphery of at least a part of the wire 21. That is, at least a portion of the wire 21 is disposed in the inner sheath 23. The inner sheath 23 is disposed in the coil sheath 11. The inner sheath 23 is, for example, a resin tube. A thickness T3 of the inner sheath 23 is about 0.3 mm. The thickness T2 of the resin tube 12 is greater than the thickness T3 of the inner sheath 23. Further, the inner sheath 23 is not fixed to the coil sheath 11, the wire 21, the connector 39, the treatment part 110 and the manipulation part 5. The inner sheath 23 is provided to secure sliding properties of the wire 21 in the coil sheath 11. Therefore, the inner sheath 23 is movable with respect to the coil sheath in the longitudinal direction A. Further, when the wire 21 can ensure sufficient sliding properties within the coil sheath 11, the inner sheath 23 does not need to be provided.

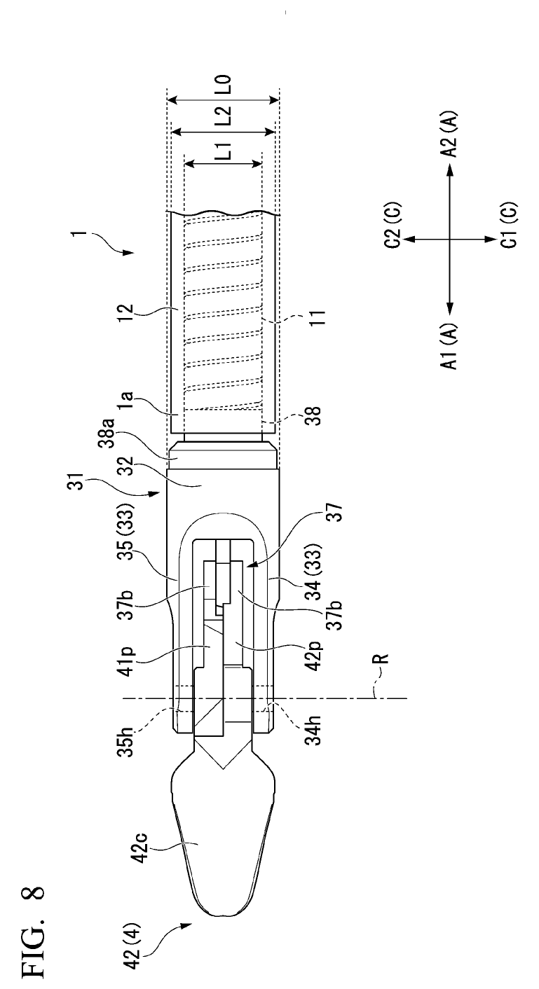

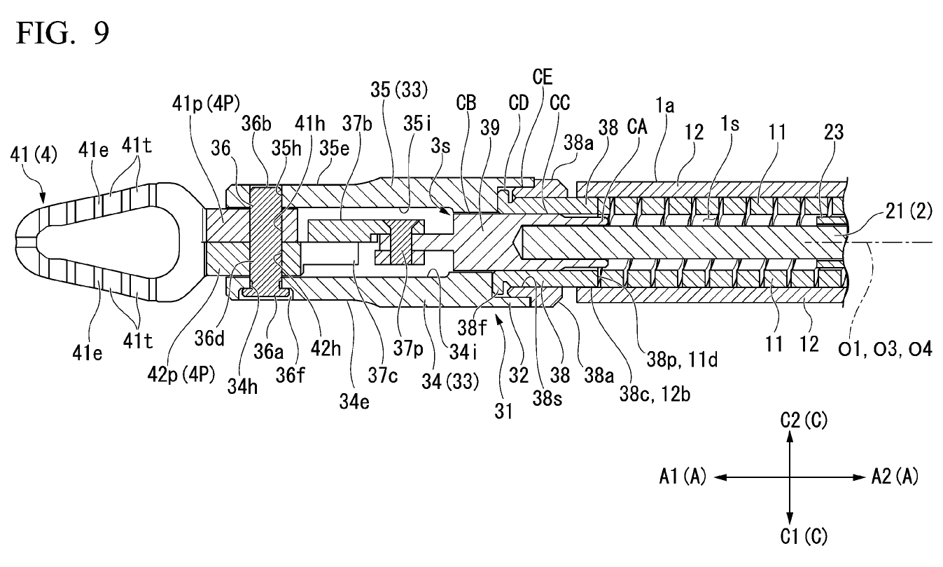

FIG. 8 is a plan view of the distal end portion of the treatment tool 100. FIG. 9 is a cross-sectional view of the distal end portion of the treatment tool 100. The support member 3 is attached to the distal end 1a of the sheath 1 and pivotably supports the forceps 4. The support member 3 includes a bracket 31, a pin 36, a link mechanism 37, a sheath connector 38, and the connector 39. The forceps 4 is supported by the pin 36 attached to the bracket 31.

The bracket (housing) 31 is formed in substantially a U shape by a metal such as stainless steel or the like when viewed in a plan view from the upward/downward direction B. Further, the term “substantially U shape” includes not only a strict U shape but also a shape close to a U shape. The bracket 31 is formed by cutting. The bracket 31 has a support main body 32 formed in a substantially cylindrical shape, and a pair of arms 33 (a first arm 34 and a second arm 35). Further, the term “substantially cylindrical shape” includes not only a strict cylindrical shape but also a shape close to a cylindrical shape, for example, a shape in which a part of the outer surface is flat. The bracket 31 covers a part of the forceps 4. Specifically, the proximal end portion of the forceps 4 is disposed between the first arm 34 and the second arm 35.

The outer diameter L2 of the resin tube 12 is smaller than a maximum width L0 of the outer surface of the bracket 31 in the radial direction of the coil sheath 11 (L2 < L0). The thickness T2 of the resin tube 12 that covers the outer surface of the coil sheath 11 is smaller than a half of a difference between the maximum width L0 of the outer surface of the bracket 31 in the radial direction of the coil sheath 11 and the outer diameter L1 of the coil sheath 11 (T2 < (L0-L1)/2).

Since the outer diameter L2 of the resin tube 12 is smaller than the maximum width L0 of the outer surface of the bracket 31, there is a large clearance between the channel 216 of the endoscope 200 and the resin tube 12 even when the treatment tool 100 is inserted into the channel 216 of the endoscope 200, and suction performance using the channel 216 of the endoscope 200 can be maintained. Further, when the outer diameter L2 of the resin tube 12 is smaller than the maximum width L0 of the outer surface of the bracket 31 at least at the portion inserted into the channel 216 of the endoscope 200, suction performance using the channel 216 of the endoscope 200 can be maintained. In addition, when the outer diameter L2 of the resin tube 12 is smaller than the maximum width L0 of the outer surface of the bracket 31 at least at a distal end portion 1d, suction performance using the channel 216 of the endoscope 200 can be maintained. As shown in FIG. 5, the distal end portion 1d includes a part of the resin tube 12 that covers at least a foremost distal end 11a of the coil sheath 11. Specifically, the distal end portion 1d includes a part of the resin tube 12 that covers a portion in which a proximal end surface 38p of the sheath connector 38 and a distal end end surface 11d of the coil sheath 11 are joined. Further, the distal end portion 1d may include a part of the resin tube 12 that covers the sheath connector 38.

The proximal end portion of the support main body 32 covers the outside of the distal end portion of the sheath connector 38. The support main body 32 is supported so as to be pivotable about a longitudinal axis of the sheath 1 relative to the sheath connector 38. A center axis O3 of the support member 3 in the longitudinal direction A substantially coincides with a center axis O1 of the sheath 1 in the longitudinal direction A. Further, the term “substantially coincide with” includes aspects that coincide with strictly as well as aspects that almost coincide with. An internal space 3s of the support main body 32 communicates with the internal space 1s of the sheath 1. The connector 39 is inserted through the internal space 3s of the support main body 32. The distal end of the wire 21 is located inside the support main body 32 when the forceps 4 is in the closed state.

As shown in FIG. 9, the sheath connector 38 is connected to the distal end 1a of the sheath 1. The proximal end of the sheath connector 38 is welded to the distal end of the coil sheath 11 of the sheath 1. Specifically, the proximal end surface 38p of the sheath connector 38 and the distal end surface 11d of the coil sheath 11 are joined. An outer surface 38c of at least a part of the proximal end portion of the sheath connector 38 is in close contact with an inner surface 12b of the distal end portion of the resin tube 12. A sheath connector holder 38a configured to support the sheath connector 38 is welded to the proximal end portion of the support main body 32. An outer surface 38s of the distal end portion of the sheath connector 38 is covered with the proximal end portion of the support main body 32 and the sheath connector holder 38a. The sheath connector 38 and the sheath connector holder 38a are configured to be relatively rotatable around the center axis (longitudinal axis) O3 as the center of rotation. The distal end of the sheath connector 38 is formed with a flange 38f that expands outward in the radial direction. Since the flange 38f engages with the sheath connector holder 38a, the sheath connector 38 does not separate from the support main body 32 and the sheath connector holder 38a.

The connector 39 is formed in a cylindrical shape and inserted into the internal space 3s of the support main body 32. The connector 39 can be advanced and retracted along the longitudinal direction A. The distal end of the wire 21 is attached to the proximal end side A2 of the connector 39 by welding or the like.

Further, the wire 21 may be directly connected to the proximal end side of the connector 39, or may be connected to the proximal end side via a connecting member (not shown).

When the wire 21 is rotated about the center axis O3 as the center of rotation, the welded connector 39, the link mechanism 37, the pin 36, the bracket 31, and the sheath connector holder 38a rotate in conjunction with each other. Meanwhile, the coil sheath 11 and the sheath connector 38 do not rotate in response to this rotation. That is, when the wire 21 is rotated around the longitudinal axis, the connector 39, the link mechanism 37, the pin 36, the bracket 31, and the sheath connector holder 38a are configured to rotate relative to the coil sheath 11 and the sheath connector 38. The outer diameter L4 of the wire 21 is large enough to easily transmit rotation around the center axis O3 as the center of rotation, making it easy to pivot the forceps 4 connected to the link mechanism 37.

As shown in FIG. 9, a gap between the proximal end of the connector 39 and the sheath connector 38 is referred to as a first clearance CA, a gap between the connector 39 and the pair of arms 33 is referred to as a second clearance CB, a gap between the connector 39 and the sheath connector 38 is referred to as a third clearance CC, a gap between the sheath connector 38 and the support main body 32 is referred to as a fourth clearance CD, and a gap between the sheath connector holder 38a and the support main body 32 is referred to as a fifth clearance CE.

It is necessary to secure a gap for welding the wire 21 and the connector 39, but if this gap becomes too large, the forceps 4 is more likely to open to one side. For this reason, the first clearance CA is desirably greater than the second clearance CB, the third clearance CC, and the fifth clearance CE. Further, the second clearance CB, the third clearance CC and the fifth clearance CE are desirably smaller than the fourth clearance CD.

The pair of arms 33 (the first arm 34 and the second arm 35) extend from the support main body 32 to the distal end side A1. The first arm 34 and the second arm 35 are provided on either side of the center axis O3 in the widthwise direction C at equal distances from the center axis O3. Further, the first arm 34 and the second arm 35 do not necessarily need to be provided at equal positions, and can be changed as appropriate depending on the structure of the link mechanism. The first arm 34 and the second arm 35 are symmetrical with respect to the vertical plane VP passing through the center axis O3.

The first arm 34 is formed in a flat plate shape extending in the longitudinal direction A. The plate thickness direction of the first arm 34 substantially coincides with the widthwise direction C. Further, the term “substantially coincide with” includes aspects that coincide with strictly as well as aspects that almost coincide with. The proximal end side A2 of the first arm 34 is continuous with the support main body 32.

A first through-hole 34h penetrating in the plate thickness direction is formed in the distal end side A1 of the first arm 34. The first through-hole 34h opens to the outside in the widthwise direction C (an outer surface 34e) in the first arm 34. In addition, the first through-hole 34h opens on the inside in the widthwise direction C (an inner surface 34i) of the first arm 34.

The second arm 35 is formed in a flat plate shape extending in the longitudinal direction A. The plate thickness direction of the second arm 35 substantially coincides with the widthwise direction C. Further, the term “substantially coincide with” includes aspects that coincide with strictly as well as aspects that almost coincide with. The proximal end side A2 of the second arm 35 is continuous with the support main body 32.

A second through-hole 35h penetrating in the plate thickness direction is formed in the distal end side A1 of the second arm 35. The second through-hole 35h opens to the outside in the widthwise direction C (an outer surface 35e) in the second arm 35. In addition, the second through-hole 35h opens to the inside in the widthwise direction C (an inner surface 35i) in the second arm 35.

As shown in FIG. 9, the pin (shaft, rotation shaft, rotation shaft member) 36 is formed of a metal such as stainless steel or the like in a substantially cylindrical shape. The pin 36 is engaged with the first through-hole 34h and the second through-hole 35h and attached to the bracket 31. The longitudinal axis direction of the pin 36 substantially coincides with the widthwise direction C. Further, the term “substantially coincide with” includes aspects that coincide with strictly as well as aspects that almost coincide with. The pin 36 has a main body cylindrical portion 36d and a flare portion 36f.

A first end portion 36a, which is one end portion of the pin 36, is inserted through the first through-hole 34h of the first arm 34 and is attached to the bracket 31 by engaging with the first through-hole 34h. A second end portion 36b, which is the other end portion of the pin 36 is inserted through the second through-hole 35h of the second arm 35 and is attached to the bracket 31 by engaging with the second through-hole 35h. The end of the first end portion 36a is provided with the flare portion 36f hooked to the first arm 34. The flare portion 36f is specifically a flange, and has an outer diameter greater than that of the main body cylindrical portion 36d in the pin 36.

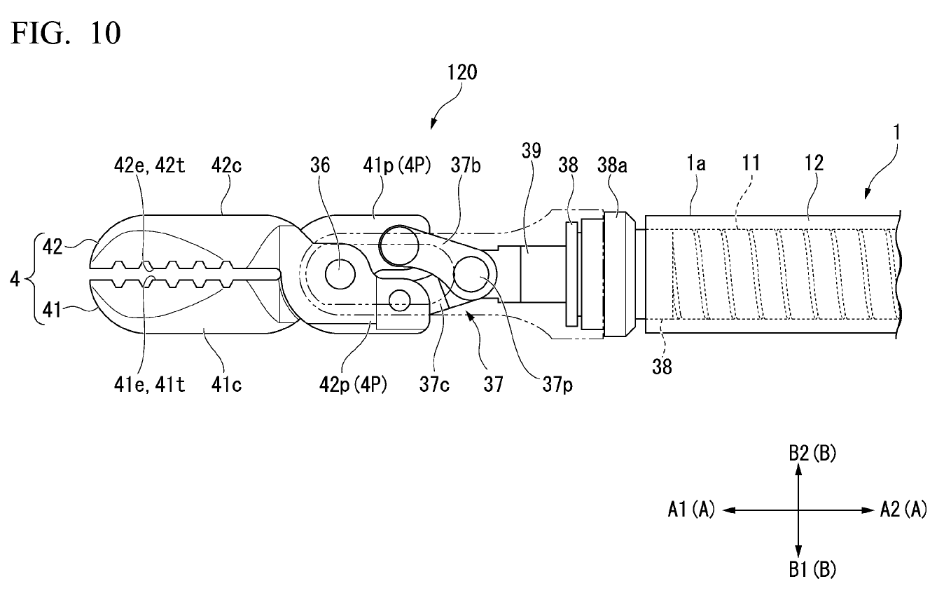

FIGS. 10-14 are views showing operations of the link mechanism 37.

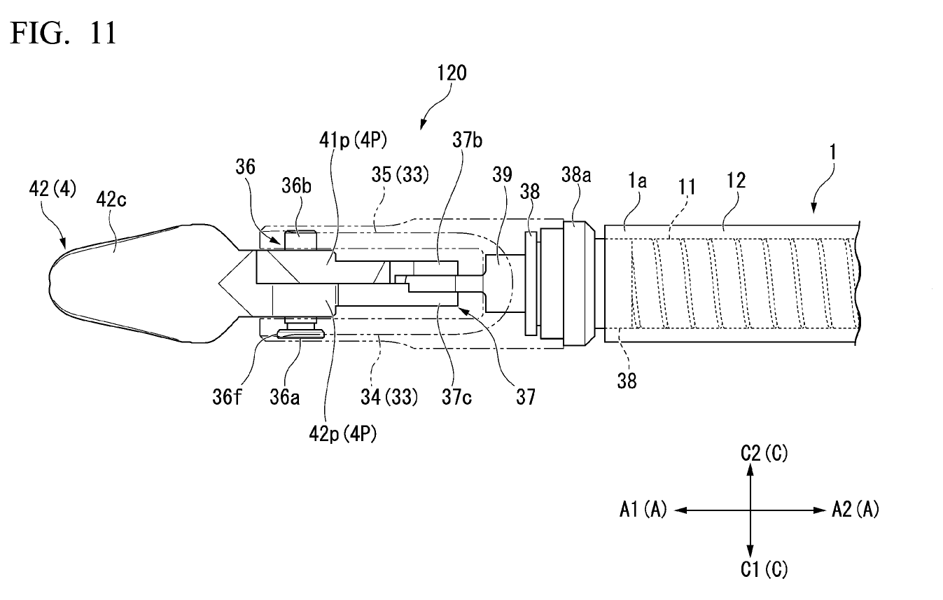

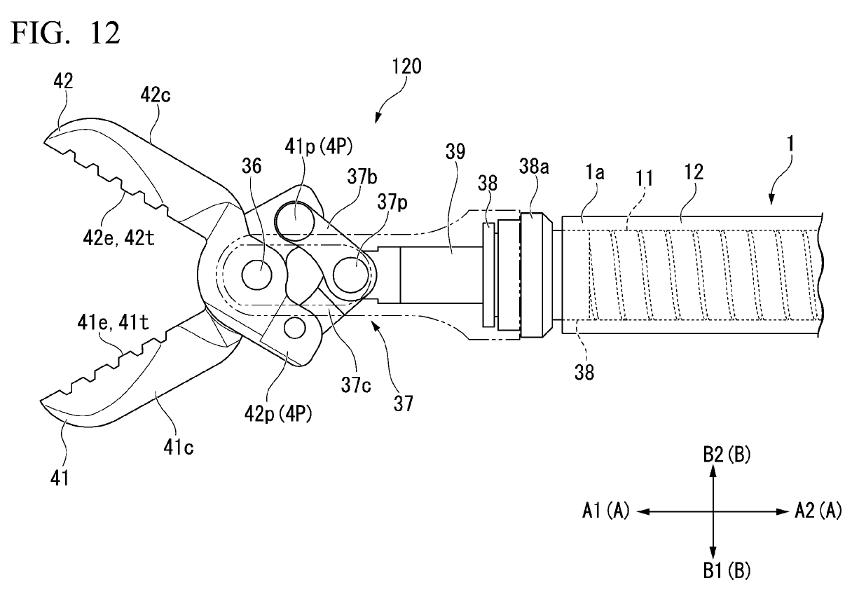

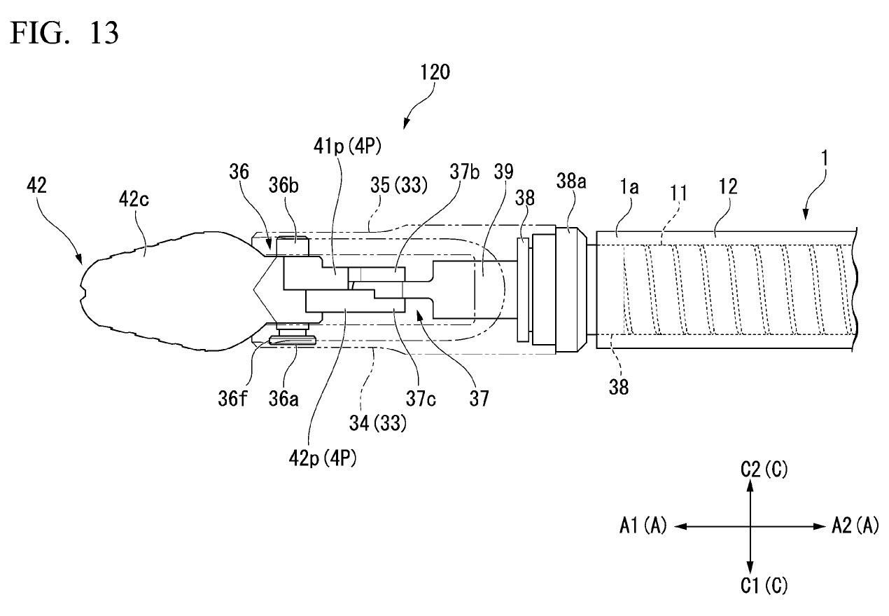

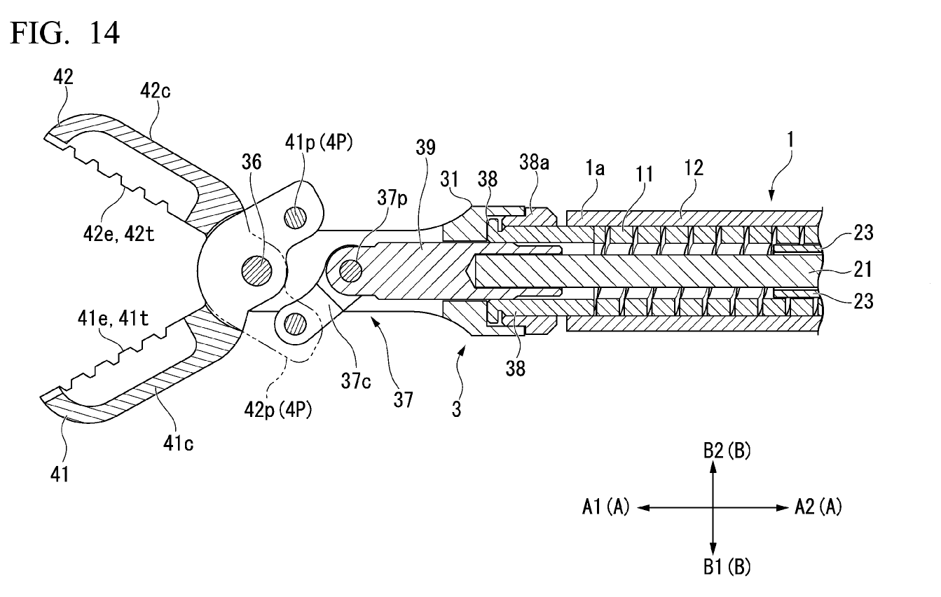

The link mechanism 37 is a link mechanism that converts the forward and rearward movement of the wire 21 in the longitudinal direction A into the opening and closing operation of the forceps 4. The link mechanism 37 has a first link 37b and a second link 37c. In FIGS. 10 and 11, the link mechanism 37 closes the forceps 4. In FIGS. 12 and 13, the link mechanism 37 opens the forceps 4. FIG. 14 is a cross-sectional view of the distal end portion of the treatment tool 100 when the forceps 4 is opened.

The first link 37b is a plate-shaped member (bar) configured to connect the connector 39 and a first forceps piece 41 of the forceps 4. The first link 37b is connected to the connector 39 via a pin 37p to be pivotable relative to the connector 39 along the vertical plane VP. In addition, the first link 37b is connected to the first forceps piece 41 to be pivotable relative to the first forceps piece 41 along the vertical plane VP.

The second link 37c is a plate-shaped member (bar) configured to connect the connector 39 and a second forceps piece 42 of the forceps 4. The second link 37c is connected to the connector 39 via the pin 37p to be pivotable relative to the connector 39 along the vertical plane VP. In addition, the second link 37c is connected to the second forceps piece 42 to be pivotable relative to the second forceps piece 42 along the vertical plane VP.

The forceps 4 is a member configured to grasp biological tissue. The forceps 4 is supported by the support member 3 to be opened and closed toward the distal end side A1. The forceps 4 extends toward a distal side A1 from the distal end of the bracket 31. In addition, the forceps 4 is located on the distal side A1 of the distal end of the sheath connector 38. The forceps 4 is made of a metal material such as stainless steel or the like and includes the first forceps piece (first grasper, first jaws) 41 and the second forceps piece (second grasper, second jaws) 42. The first forceps piece 41 and the second forceps piece 42 are also referred to as a pair of forceps pieces.

The first forceps piece 41 and the second forceps piece 42 are disposed symmetrically with respect to a center axis O4 in the longitudinal direction A of the forceps 4. The center axis O4 of the forceps 4 in the longitudinal direction A substantially coincides with the center axis O1 of the sheath 1 in the longitudinal direction A. Further, the term “substantially coincide with” includes aspects that coincide with strictly as well as aspects that almost coincide with.

In the following description, a direction in which the first forceps piece 41 is opened is referred to as “a lower side B1” in the opening/closing direction B, and a direction in which the second forceps piece 42 is opened is referred to as “an upper side B2” in the opening/closing direction B. In addition, a direction directed rightward when the proximal end side A2 is seen from the distal end side A1 is referred to as “a right side C1” in the widthwise direction C, and a direction directed leftward is referred to as “a left side C2” in the widthwise direction C.

The first forceps piece 41 is pivotally supported by the pin 36 with a center axis R of the pin 36 as the center of rotation. The first forceps piece 41 has a first cup 41c, a first edge 41e, and a first plate 41p, which are provided on the distal end side A1.

The first cup 41c is formed in a cup shape, and opens toward the second forceps piece 42 (the upper side B2) in the opening/closing direction B.

The first edge 41e is an opening edge of the first cup 41c. The first edge 41e has a first serrated portion 41t. The first serrated portion 41t is a serrated-shaped irregularity provided on the first edge 41e.

As shown in FIG. 9, the first plate (left plate, left piece) 41p is provided on the proximal end side A2 of the first cup 41c and is formed in a substantially plate shape. Further, the term “substantially plate shape” includes a strict plate shape as well as a shape close to a plate shape. The plate thickness direction of the first plate 41p substantially coincides with the widthwise direction C. Further, the term “substantially coincide with” includes aspects that coincide with strictly as well as aspects that almost coincide with. The first plate 41p has a through-hole 41h through which the pin 36 extends in the widthwise direction C.

The second forceps piece 42 is pivotally supported by the pin 36 with the center axis R of the pin 36 as the center of rotation. The second forceps piece 42 has a second cup 42c, a second edge 42e, and a second plate 42p, which are provided on the distal end side A1.

The second cup 42c is formed in a cup shape, and opens toward the first forceps piece 41 (the lower side B1) in the opening/closing direction B.

The second edge 42e is an opening edge of the second cup 42c. The second edge 42e has a second serrated portion 42t. The second serrated portion 42t is a serrated-shaped irregularity provided on the second edge 42e.

As shown in FIG. 9, the second plate (right plate, right piece) 42p is provided on the proximal end side A2 of the second cup 42c and formed in a substantially plate shape. The plate thickness direction of the second plate 42p substantially coincides with the widthwise direction C. Further, the term “substantially coincide with” includes aspects that coincide with strictly as well as aspects that almost coincide with. The second plate 42p has a through-hole 42h through which the pin 36 extends in the widthwise direction C.

The first plate 41p and the second plate 42p are disposed adjacent to each other in the leftward/rightward direction C. The first plate 41p and the second plate 42p are supported by the pin 36 that passes through them. The first plate 41p and the second plate 42p supported by the pin 36 are also referred to as “a pair of plates (pair of pieces) 4P.”

Further, one of the first forceps piece 41 and the second forceps piece 42 may be fixed to the support member 3, and the other may be pivotably supported by the support member 3.

The bracket 31, the pin 36, and the pair of plates 4P, which support the first forceps piece 41 and the second forceps piece 42 so that they can be opened and closed, are also referred to as “a bracket assembly 120.”

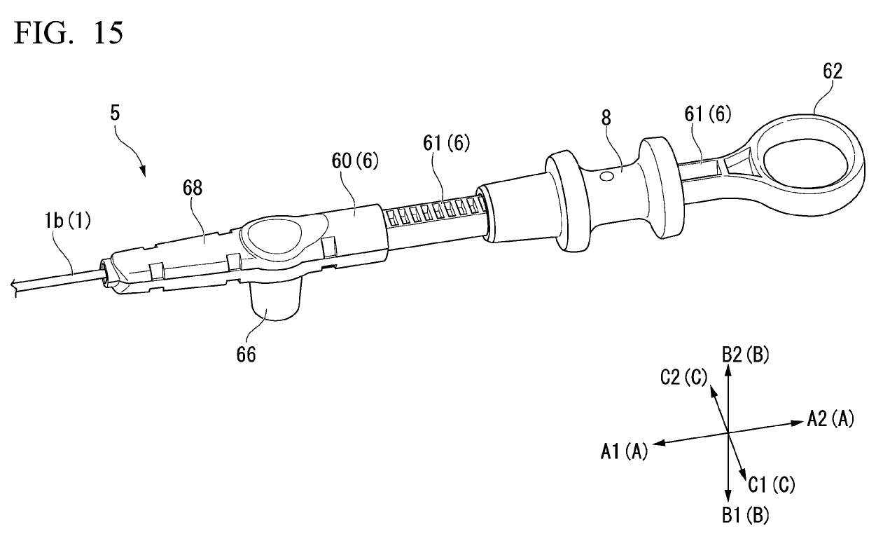

FIG. 15 is a perspective view of the manipulation part 5. FIG. 16 is a cross-sectional view of the manipulation part 5.

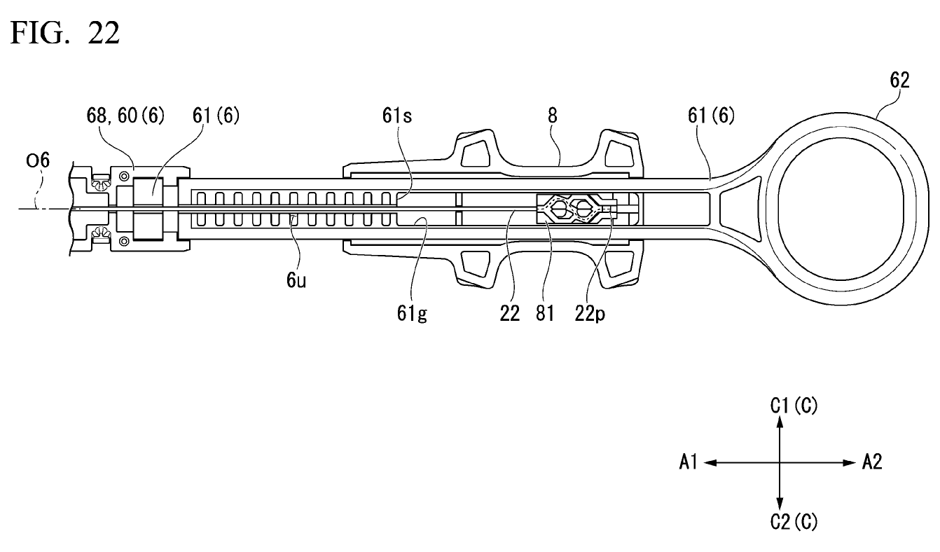

As shown in FIG. 2, the manipulation part 5 is provided on the proximal end side A2 of the sheath 1. The manipulation part 5 includes a handle main body 6, an electric connector 7, a slider 8, and a coil spring 9. The manipulation part 5 has the pipe 22 through which the wire 21 is inserted so that the wire 21 does not buckle within the manipulation part 5. A distal end 22b of the pipe 22 is inserted into the proximal end portion of the coil sheath 11. A proximal end 22p of the pipe 22 is fixed to the slider 8 together with the wire 21 (see FIG. 22). Further, if the wire 21 has sufficient rigidity to prevent buckling, the manipulation part 5 does not need to include the pipe 22.

In the following description of the manipulation part 5, a direction in which the electric connector 7 is provided relative to the handle main body 6 is referred to as “the lower side B1” in the upward/downward direction B, and a side opposite to the lower side B1 in the upward/downward direction B is referred to as “the upper side B2.” In addition, a direction perpendicular to the longitudinal axis direction A and the upward/downward direction B is referred to as “the widthwise direction C” or “the leftward/rightward direction C.” A direction directed rightward when the proximal end side A2 is seen from the distal end side A1 is referred to as “the right side C1” in the widthwise direction C, and a direction directed leftward is referred to as “the left side C2” in the widthwise direction C.

The handle main body 6 has an internal space 6s through which the wire 21 can be inserted. The wire 21 passes through the internal space of the sheath 1 and the internal space 6s of the handle main body 6 and extends to the slider 8.

The handle main body 6 has a first handle main body 60, and a second handle main body 61. The second handle main body 61 is connected to the proximal end portion of the first handle main body 60. A distal end 61b of the second handle main body 61 is disposed closer to the distal end side A1 than a proximal end 60p of the first handle main body 60. The first handle main body 60 and the second handle main body 61 are connected to each other so as to be capable of relative rotation about a center axis O6 of the pipe 22 extending in the longitudinal axis direction A. The internal space 6s is a continuous space formed in the first handle main body 60 and the second handle main body 61. The internal space 6s has an internal space 6t formed in the first handle main body 60, and a slit 6u formed in the second handle main body 61.

The first handle main body 60 has a cover 68 attached to the first handle main body 60. The cover 68 is attached to and detached from the upper side B2 of the first handle main body 60 in the upward/downward direction B. In other words, the cover 68 is attached and detached along the direction in which the electric connector 7 extends. In other words, the cover 68 is attached and detached along the direction in which the coil spring 9 expands and contracts. The cover 68 is attached to cover an upper end portion 70 of the electric connector 7. The cover 68 is attached to cover the proximal end portion of the resin tube 12, a part of the pipe 22, and the distal end portion of the second handle main body 61. The cover 68 has a claw 68s extending toward the lower side B1. The claws 68s engage with an engagement portion (groove) 60s provided on the first handle main body 60, thereby removably attaching the cover 68 to the first handle main body 60. Further, by attaching the cover 68, the internal space 6t is formed in the first handle main body 60.

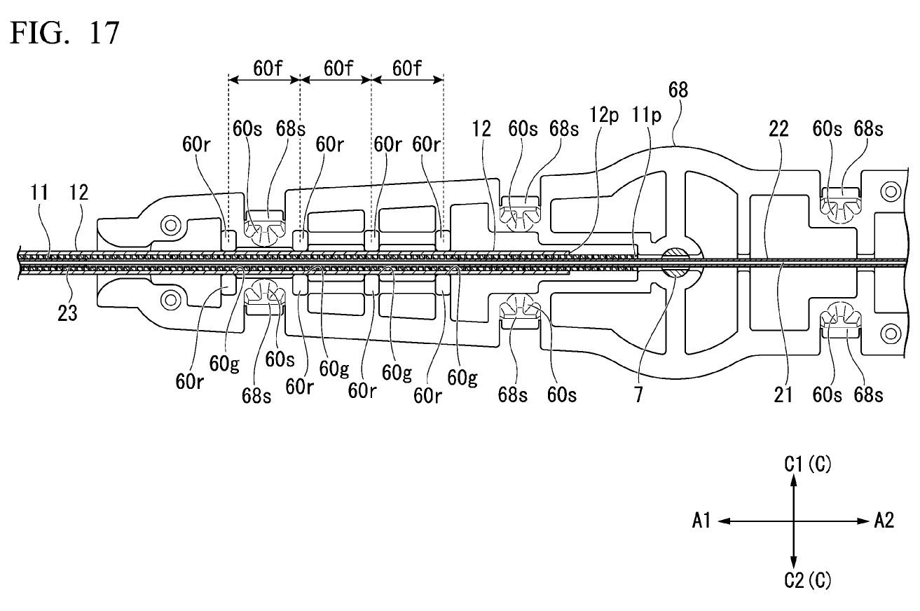

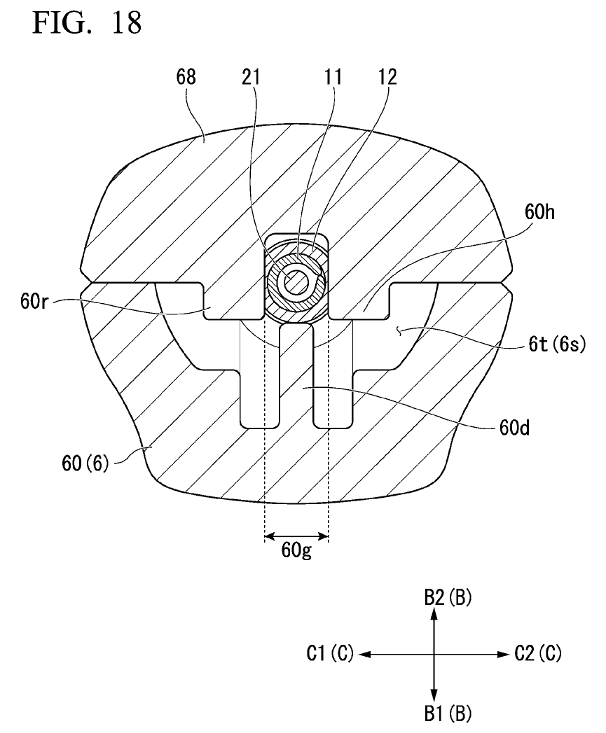

FIG. 17 is a view showing the cover 68. FIG. 18 is a cross-sectional view along line X-X shown in FIG. 16. The cover 68 has a plurality of partition walls (ribs) 60r. The plurality of partition walls 60r are arranged side by side along the longitudinal direction A with a gap (space) 60f therebetween. It is desirable to have two or more of the partition walls 60r arranged side by side. The partition walls 60r extend in the leftward/rightward direction C and have a gap (groove) 60g in the intermediate portion of the leftward/rightward direction C. In other words, the partition walls 60r extend in a direction perpendicular to the direction in which the wire 21 or the pipe 22 extends, and have the gap 60g in the intermediate portion in this direction. In addition, the partition walls 60r extend in a direction perpendicular to the direction in which the electric connector 7 extends, and have the gap 60g in the intermediate portion in this direction. Also, the partition walls 60r extend in a direction intersecting an attachment direction of the cover 68 and a longitudinal direction of the bracket (housing) 31. A length of the gap 60g in the leftward/rightward direction C is smaller than the outer diameter L2 of the resin tube 12. The length of the gap 60g in the leftward/rightward direction C is 1.74 mm to 1.76 mm. Further, the plurality of partition walls 60r may be provided on the first handle main body 60. The first handle main body 60 has a support portion 60d that supports the lower side B1 of the resin tube 12.

As shown in FIG. 16, the coil sheath 11 and the resin tube 12 extend closer to the proximal end side A2 than the plurality of partition walls 60r. The plurality of partition walls 60r are disposed between a distal end 60b of the first handle main body 60 and a proximal end 11p of the coil sheath 11. The plurality of partition walls 60r are disposed between the distal end 60b of the first handle main body 60 and a proximal end 12p of the resin tube 12. The proximal end 11p of the coil sheath 11 is disposed closer to the proximal end side A2 than the plurality of partition walls 60r, closer to the distal end side A1 than the electric connector 7, and closer to the distal end side A1 than the distal end 61b of the second handle main body 61. The proximal end 12p of the resin tube 12 is disposed closer to the proximal end side A2 than the plurality of partition walls 60r, closer to the distal end side A1 than the electric connector 7, and closer to the distal end side A1 than the distal end 61b of the second handle main body 61. The proximal end 12p of the resin tube 12 is disposed closer to the distal end side A1 than the proximal end 11p of the coil sheath 11. The distal end 22b of the pipe 22 is disposed closer to the proximal end side A2 than the plurality of partition walls 60r, closer to the distal end side A1 than the proximal end 11p of the coil sheath 11, closer to the distal end side A1 than the electric connector 7, and closer to the distal end side A1 than the distal end 61b of the second handle main body 61.

A specific method for fixing the resin tube 12 will be described below. Before attaching the cover 68 to the first handle main body 60, the electric connector 7, the coil spring 9, or the like, is positioned on the first handle main body 60 and disposed thereon. Next, in the process of attaching the cover 68 to the first handle main body 60, the resin tube 12 is pressed against the plurality of partition walls 60r, and the resin tube 12 is gradually pressed into the plurality of gaps 60g. When the cover 68 is completely attached to the first handle main body 60, the resin tube 12 is inserted into the plurality of gaps 60g, the resin tube 12 is pressed between the proximal end portion of the coil sheath 11 and the first handle main body 60, and thus, the coil sheath 11 is fixed to the first handle main body 60. The resin tube 12 is pressed between the proximal end portion of the coil sheath 11 and the first handle main body 60, and thus, the coil sheath 11 is fixed to the first handle main body 60.

The resin tube 12 is pressed and fixed. If the cover 68 is removed from the first handle main body 60 and the resin tube 12 is removed, the resin tube 12, which is made of polyethylene, will have marks formed by the partition walls 60r. The pressed mark is, for example, a trace, in which the resin tube 12 is thinner than the unpressed part, has a concave shape, or has cracks.

The partition walls 60r extend in the leftward/rightward direction C, and the resin tube 12 inserted into the gap 60g is pressed from the leftward/rightward direction C. Meanwhile, the cover 68 is attached from the upper side B2 of the first handle main body 60 along the upward/downward direction B. For this reason, even if the cover 68 is attached from the upward/downward direction B, the elastic force of the resin tube 12 does not act in a direction in which the cover 68 is pulled away from the first handle main body 60. Further, the partition walls 60r do not necessarily have to extend strictly in the leftward/rightward direction C. If the partition walls 60r extend in a direction intersecting the attachment direction of the cover 68, the cover 68 will not come off easily and the fixing strength can be sufficiently ensured.

The handle main body 6 has a thumb ring 62, and a connector support portion 64. The thumb ring 62 is provided on the proximal end side A2 of the second handle main body 61. A surgeon can support the second handle main body 61 by inserting the thumb into the thumb ring 62.

The connector support portion 64 is provided on the first handle main body 60. The connector support portion 64 supports the electric connector 7. As shown in FIG. 16, the connector support portion 64 has a through-hole 65 penetrating in the upward/downward direction B, and a cylindrical plug socket 66 formed on the lower side B1 of the through-hole 65. In other words, the through-hole 65 passes through the first handle main body 60 in a direction perpendicular to the direction in which the wire 21 or the pipe 22 extends.

The through-hole 65 is a through-hole through which a reduced diameter portion 75 of the electric connector 7 is inserted. A length of the through-hole 65 in the upward/downward direction may be slightly smaller than the length of the reduced diameter portion 75 in the upward/downward direction.

The plug socket 66 is formed in a cylindrical shape and surrounds a power plug 74, which is a part of the electric connector 7. A gap 66g that allows attachment of a power cable (active cord) is provided between the power plug 74 of the electric connector 7 and the plug socket 66.

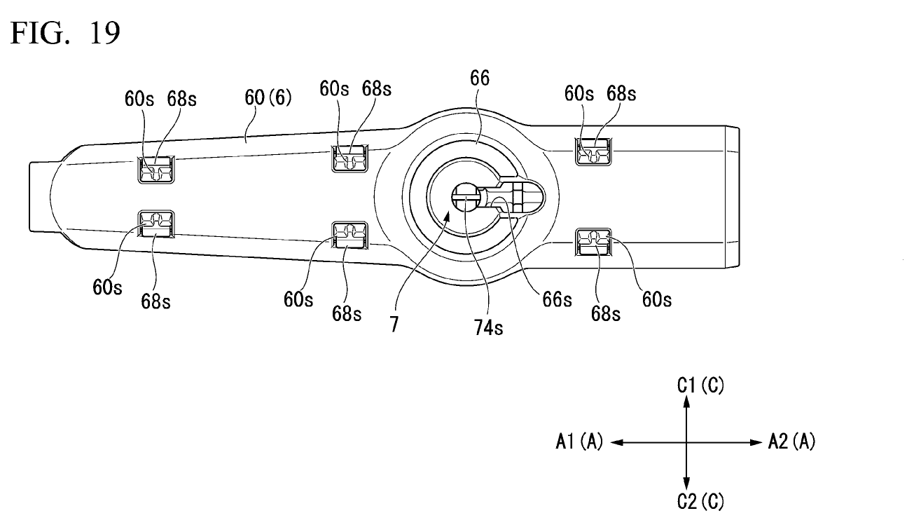

FIGS. 19-21 are views showing the handle main body 6.

The plug socket 66 is formed with a slit 66s extending in the upward/downward direction. The slit 66s is provided on the proximal end side A2 of the plug socket 66. For this reason, the plug socket 66 is likely to bend in the widthwise direction C.

The electric connector 7 is supported by the connector support portion 64, is a conductive member extending in a direction intersecting the longitudinal axis of the wire 21, and is formed in a substantially cylindrical shape. Further, the term “substantially cylindrical shape” includes not only a strictly cylindrical shape but also a shape that is close to a cylindrical shape.

The electric connector 7 has the upper end portion 70, a connecting portion 71, the power plug 74, and the reduced diameter portion 75. The electric connector 7 extends between the power plug 74 and the upper end portion 70 supported by a coil spring support portion. The connecting portion 71 and the reduced diameter portion 75 are disposed between the power plug 74 and the upper end portion 70. The upper end portion 70 is provided on the upper side B2 of the connecting portion 71. The direction in which the electric connector 7 extends intersects the direction in which the wire 21 extends.

As shown in FIG. 16, the connecting portion 71 is formed in a substantially cylindrical shape, and provided on the upper side of the electric connector 7. Further, the term “substantially cylindrical shape” includes not only a strictly cylindrical shape but also a shape that is close to a cylindrical shape. The connecting portion 71 is disposed in the internal space 6t. The connecting portion 71 is electrically connected to a part of the pipe 22 protruding from the proximal end 11p of the coil sheath 11 to the proximal end side A2 in the internal space 6t of the first handle main body 60. An insertion passage 72 is formed in the connecting portion 71. That is, the insertion passage 72 extending in the longitudinal axis direction A of the first handle main body 60 is formed in the proximal end portion of the electric connector 7.

The pipe 22 is inserted into the insertion passage 72. That is, the insertion passage 72 is a through-hole formed along the longitudinal axis direction A in which the pipe 22 extends, and the pipe 22 and the wire 21 passing through the pipe 22 are inserted therethrough so as to be able to move forward and rearward. The insertion passage 72 is disposed in the internal space 6t, and the insertion passage 72 and the pipe 22 are parallel in the internal space 6t.

The power plug 74 is a plug provided on the lower side B1 of the electric connector 7, to which a power cable (active cord) is connected. The power plug 74 is formed with a slit 74s extending in the upward/downward direction B. The slit 74s penetrates in the longitudinal direction A. For this reason, the power plug 74 is likely to bend in the widthwise direction C.

For this reason, even when the power cable (active cord) is inserted into the plug socket 66 at an angle relative to the upward/downward direction B, the direction in which the power cable is likely to be inserted diagonally into the plug socket 66 is different from the direction in which the power plug 74 is likely to bend, so deformation of the power plug 74 can be prevented.

The reduced diameter portion 75 is an intermediate portion in the upward/downward direction B, and is located between the insertion passage 72 and the power plug 74. An outer diameter of the reduced diameter portion 75 is smaller than an outer diameter of the connecting portion 71 and an outer diameter of the power plug 74. The reduced diameter portion 75 passes through the through-hole 65 of the first handle main body 60 and is fixed thereto.

The connecting portion 71 and the power plug 74 disposed on both sides of the reduced diameter portion 75 in the upward/downward direction B cannot be inserted through the through-hole 65 of the first handle main body 60. By engaging the connecting portion 71 and the power plug 74 with the opening portions at both ends of the through-hole 65 in the upward/downward direction B, the movement range of the electric connector 7 in the upward/downward direction B is restricted to a predetermined range.

The electric connector (connecting member, plug) 7 can be connected to a high frequency power supply (not shown) via a power cable, and the electric connector 7 electrically and physically connected to the pipe 22 and the wire 21 can supply high frequency current supplied from the high frequency power supply to the forceps 4 via the pipe 22 and the wire 21.

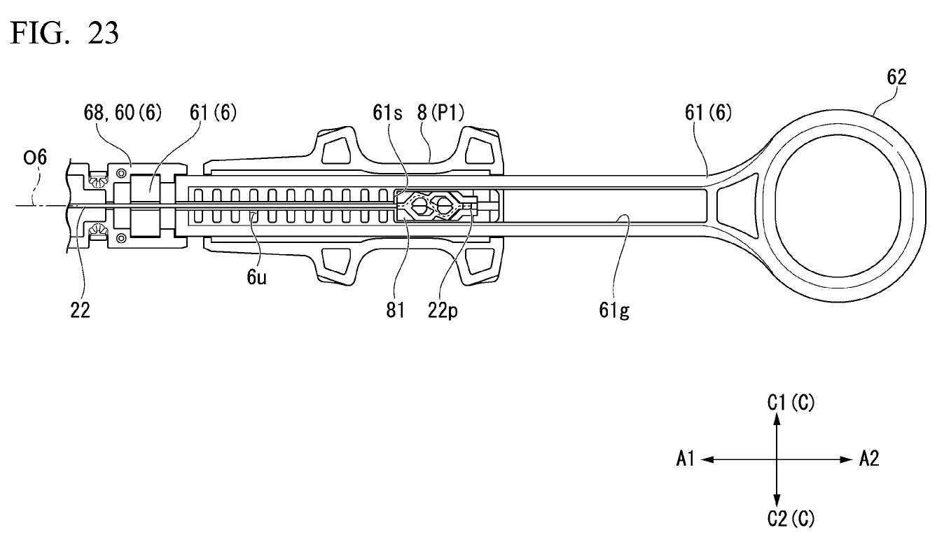

FIGS. 22 and 23 are cross-sectional views of the second handle main body 61 and the slider 8.

The slider 8 is attached so as to be movable forward and rearward in the longitudinal axis direction A along the second handle main body 61. The slider 8 can move forward and rearward along the longitudinal axis relative to the second handle main body 61. The proximal end portion of the wire 21 and the proximal end portion of the pipe 22 are connected to the slider 8. The surgeon moves the slider 8 forward and rearward relative to the second handle main body 61, causing the wire 21 and the pipe 22 to move forward and rearward. The surgeon pivots the second handle main body 61 and the slider 8 about the longitudinal axis relative to the first handle main body 60, causing the wire 21 and the pipe 22 to rotate relative to the first handle main body 60. As a result, the connector 39, the link mechanism 37, the pin 36, the bracket 31 and the sheath connector holder 38a are configured to rotate relative to the coil sheath 11 and the sheath connector 38.

The slider 8 has a slide portion 81 that moves forward and rearward along a groove 61g formed in the second handle main body 61. The proximal end portion of the wire 21 and the proximal end portion of the pipe 22 are fixed to the slide portion 81. The groove 61g is formed along the longitudinal axis of the second handle main body 61. An abutment surface 61s is formed on the distal end side A1 of the groove 61g. By moving the slider 8 to the distal end side A1 and causing the slide portion 81 to contact the abutment surface 61s, the slider 8 is positioned at a first position P1, which is the position closest to the distal end side A1. As shown in FIG. 23, when the slider 8 is at the first position P1, the slider 8 is disposed at a position away from the first handle main body 60. Further, when the slider 8 is at the first position P1, the slider 8 may be disposed at a position where the slider 8 contacts the first handle main body 60.

The pipe 22 through which the wire 21 is inserted moves forward and backward through the slit 6u extending in the longitudinal direction A. The distal end of the slit 6u is open at the distal end 61b of the second handle main body 61. The proximal end of the slit 6u is open in the groove 61g. An inner diameter of the slit 6u is greater than an outer diameter of the pipe 22 and smaller than an outer diameter of the distal end 61b of the second handle main body 61. The pipe 22 passes through the groove 61g and extends to the slide portion 81.

The coil spring (elastic member, elastic body) 9 electrically connects the pipe 22 and the wire 21 to the electric connector 7 by applying a biasing force to the pipe 22. A part (the connecting portion 71) of the electric connector 7 passes through the coil spring 9. The coil spring 9 is disposed between the pipe 22 and the electric connector 7 in the internal space 6t of the handle main body 6 while being compressed. The coil spring 9 is a conductive compression spring, and an elastic force is applied in the direction in which the electric connector 7 extends. For this reason, the coil spring 9 is in direct contact with the pipe 22 and presses the pipe 22 against the electric connector 7. In a state in which the pipe 22 is pressed against the electric connector 7, the pipe 22 and the wire 21 can move forward and rearward (swing) along the longitudinal axis of the pipe 22, and can pivot (swing) in a circumferential direction relative to the longitudinal axis of the pipe 22.

To dispose the forceps 4 into the appropriate treatment position, the surgeon grasps the slider 8 and moves it forward and rearward or pivots it, thereby advancing and retracting or pivoting the forceps 4. Even when the slider 8 moves forward and rearward relative to the second handle main body 61 or when the second handle main body 61 and the slider 8 pivot relative to the first handle main body 60, the coil spring 9 presses the pipe 22 against the electric connector 7, thereby reliably ensuring electrical connection of the pipe 22 and the wire 21 passing through the pipe 22 to the electric connector 7.

The surgeon energizes the wire 21 and the pipe 22 with a high frequency current. Regardless of which direction of the manipulation part 5 perpendicular to the longitudinal axis direction A faces the vertical lower side, at least a part of the insertion passage 72 is in electrically conductive contact with the pipe 22. For this reason, regardless of the orientation of the manipulation part 5, high frequency current is passed from the electric connector 7 to the wire 21 and the pipe 22, and the forceps 4 can be used to stop bleeding in the bleeding area or to treat incisions.

According to the treatment tool for an endoscope 100 of the embodiment, treatment parts such as the forceps 4 can be easily pivoted, and suction performance using the endoscope channel can be maintained.

Hereinabove, the first embodiment of the present disclosure has been described in detail with reference to the accompanying drawings, but the specific configuration is not limited to this embodiment, and design changes are also included without departing from the spirit of the present disclosure. In addition, the components shown in the above-mentioned embodiment and variant can be configured in any suitable combination.

### Variant

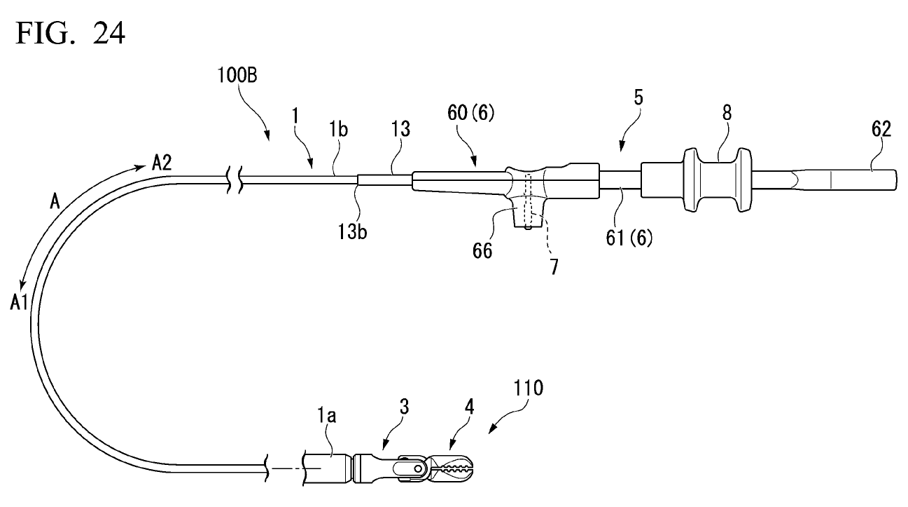

FIG. 24 is a view showing a treatment tool 100B according to a variant of the treatment tool 100.

The treatment tool 100B further includes a kink restrictor 13 provided in the vicinity of the proximal end 1b of the sheath 1 to improve the break resistance of the sheath 1 and prevent the sheath 1 from kinking. The kink restrictor 13 is attached to the outer periphery of the resin tube 12. The kink restrictor 13 is made of a highly rigid material such as elastomer or resin.

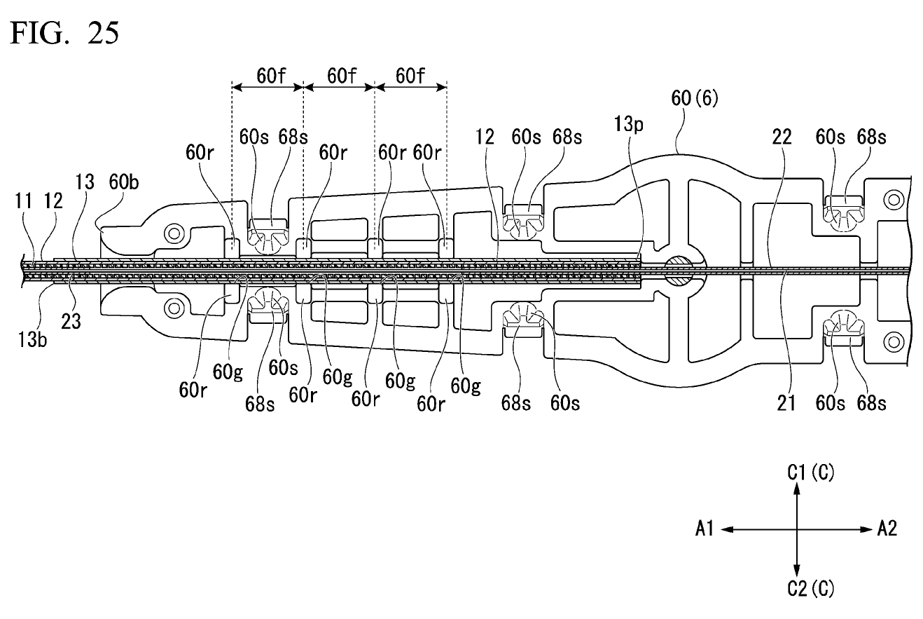

FIG. 25 is a cross-sectional view of a manipulation part of the treatment tool 100B.

A distal end 13b of the kink restrictor 13 has a length in the longitudinal axis direction shorter than that of the coil sheath 11, and for example, is disposed on the distal end side A1 by several centimeters to several tens of centimeters from the distal end 60b of the first handle main body 60. A proximal end 13p of the kink restrictor 13 is disposed closer to the proximal end side A2 than the plurality of partition walls 60r, and closer to the distal end side A1 than the electric connector 7. The kink restrictor 13 and the resin tube 12 are pressed between the proximal end portion of the coil sheath 11 and the first handle main body 60, thereby fixing the coil sheath 11 to the first handle main body 60. Further, the coil sheath 11 may be a tube or a sheath formed of a resin. In addition, the coil sheath 11 may not be provided. Further, in the variant, the same components as those described in the above-mentioned embodiment are designated by the same reference signs and redundant explanations will be omitted. The components with the same reference signs have the same effects as those described in the above-mentioned embodiment.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A treatment tool for an endoscope comprising:
a coil sheath;
a resin tube configured to cover an outer periphery of the coil sheath;
a sheath connector connected to a distal end of the coil sheath;
a distal member located distally relative to a distal end of the sheath connector; and
a housing configured to support the distal member,
wherein a proximal portion of the housing covers a distal portion of the sheath connector from outside and is supported pivotably around a longitudinal axis of the coil sheath relative to the sheath connector,
a distal end surface of the coil sheath is joined to a proximal end surface of the sheath connector, and
an outer diameter of at least a part of the resin tube is smaller than a maximum width of an outer surface of the housing in a radial direction of the coil sheath.

2. The treatment tool for an endoscope according to claim 1, wherein an outer diameter of the distal portion of the resin tube is smaller than the maximum width of the outer surface of the housing in the radial direction.

3. The treatment tool for an endoscope according to claim 1, wherein an inner surface of the resin tube is in close contact with an outer surface of at least a part of the sheath connector.

4. The treatment tool for an endoscope according to claim 1, wherein an inner sheath is movable in the coil sheath, and
a thickness of the resin tube is greater than a thickness of the inner sheath.

5. The treatment tool for an endoscope according to claim 1, wherein a material of the resin tube is polyethylene.

6. The treatment tool for an endoscope according to claim 1, wherein the coil sheath is a flat wire coil.

7. The treatment tool for an endoscope according to claim 1, wherein a thickness of the resin tube that covers an outer surface of the coil sheath is smaller than a half of a difference between the maximum width of the outer surface of the housing in the radial direction and the outer diameter of the coil sheath.

8. The treatment tool for an endoscope according to claim 1, comprising:
a wire inserted through the coil sheath; and
a pair of forceps pieces connected to a distal end of the wire,
wherein the housing pivotably supports the pair of forceps pieces.

9. A treatment tool for an endoscope comprising:
a coil sheath;
a resin tube configured to cover an outer surface of at least a proximal portion of the coil sheath; and
a handle main body disposed on the proximal portion of the coil sheath,
wherein the proximal portion of the coil sheath is inserted into the handle main body, and
the resin tube is pressed between the proximal portion of the coil sheath and the handle main body to fix the coil sheath to the handle main body.

10. The treatment tool for an endoscope according to claim 9, having a cover attached to the handle main body,
wherein the cover has a plurality of partition walls extending in a direction intersecting an attachment direction of the cover, and
the resin tube is pressed between the proximal portion of the coil sheath and the plurality of partition walls.

11. The treatment tool for an endoscope according to claim 9, wherein the handle main body has a first handle and a second handle disposed pivotably relative to the first handle around a longitudinal axis of the wire, and
the resin tube is fixed to the first handle.

12. The treatment tool for an endoscope according to claim 11, comprising:
a pair of forceps pieces located distally relative to a distal end of the coil sheath; and
a wire connected to the pair of forceps pieces and disposed in the coil sheath,
wherein the second handle has a slider to which a proximal portion of the wire is connected, and
the slider is configured to move in a direction along the longitudinal axis of the wire to the second handle.

13. The treatment tool for an endoscope according to claim 12, wherein the second handle has a groove extending along the longitudinal axis,
the slider has a slide portion configured to move in a direction along the longitudinal axis of the wire along the groove, and
the slide portion comes into contact with an abutment surface formed on a distal end side of the groove, and thus, the slider is positioned separated from the first handle.

14. A treatment tool for an endoscope comprising:
a coil sheath;
a handle main body connected to a proximal portion of the coil sheath;
a cover attached to the handle main body;
a resin tube configured to cover an outer surface of at least the proximal portion of the coil sheath;
a sheath connector connected to a distal end of the coil sheath;
a distal member located distally relative to a distal end of the sheath connector; and
a housing configured to support the distal member and cover a part of the distal member,
wherein the handle main body has a plurality of partition walls extending in a direction intersecting an attachment direction of the cover and arranged side by side with a first gap in a direction along a longitudinal axis of the sheath,
each of the plurality of partition walls has a second gap in an intermediate portion in an extending direction of the plurality of partition walls,
the proximal portion of the coil sheath is fixed within the second gap, and
an outer diameter of a distal portion of the resin tube is greater than a width of the second gap and smaller than a maximum width of the housing.

15. The treatment tool for an endoscope according to claim 14, wherein an inner surface of the resin tube is in close contact with an outer surface of at least a part of the sheath connector.

16. The treatment tool for an endoscope according to claim 14, wherein an inner sheath is disposed in the coil sheath, and
a thickness of the resin tube is greater than a thickness of the inner sheath.

17. The treatment tool for an endoscope according to claim 14, wherein a material of the resin tube is polyethylene.

18. The treatment tool for an endoscope according to claim 14, wherein the coil sheath is a flat wire coil.

19. The treatment tool for an endoscope according to claim 14, wherein a thickness of the resin tube that covers an outer surface of the coil sheath is smaller than a half of a difference between a maximum width of the outer surface of the housing in a radial direction of the coil sheath and the outer diameter of the coil sheath.

20. The treatment tool for an endoscope according to claim 14, comprising:
a wire inserted through the coil sheath; and
a pair of forceps pieces connected to a distal end of the wire,
wherein the housing pivotably supports the pair of forceps pieces.
